(19) United States
(12) Patent Application Publication
(10) Pub. No.: US 2024/0387713 A1
(43) Pub. Date: Nov. 21, 2024

(54) SEMICONDUCTOR DEVICE

(71) Applicant: FUJI ELECTRIC CO., LTD., Kawasaki-shi (JP)

(72) Inventor: Masayuki MOMOSE, Matsumoto-city (JP)

(73) Assignee: FUJI ELECTRIC CO., LTD., Kawasaki-shi (JP)

(21) Appl. No.: 18/585,175

(22) Filed: Feb. 23, 2024

(30) Foreign Application Priority Data
May 19, 2023 (JP) 2023-082676

(51) Int. Cl. H01L 29/739; G01K 7/01; H01L 27/07; H01L 29/78; H01L 29/861

(52) U.S. Cl. CPC H01L 29/7397; G01K 7/01; H01L 27/0727; H01L 29/7813; H01L 29/861

(57) ABSTRACT

A semiconductor device includes: a drift layer of a first conductivity-type; a base region of a second conductivity-type provided on a top surface side of the drift layer; a main region of the first conductivity-type provided on a top surface side of the base region; a first gate electrode buried in a first trench in contact with the main region and the base region with a gate insulating film interposed; a well region of the second conductivity-type provided on the top surface side of the drift layer; a temperature detector provided on a top surface side of the well region with an insulating film interposed; and a second gate electrode buried in a second trench provided in the well region and at least partly located immediately under the temperature detector with the gate insulating film interposed.

### CROSS-REFERENCE TO RELATED APPLICATION

This application claims benefit of priority under 35 USC 119 based on Japanese Patent Application No. 2023-082676 filed on May 19, 2023, the entire contents of which are incorporated by reference herein.

### BACKGROUND OF THE INVENTION

### 1. Field of the Invention

The present invention relates to semiconductor devices.

### 2. Description of the Related Art

JP 2008-235405 A discloses a semiconductor device including a temperature-sensing element in an IGBT region and having a trench gate structure under the temperature-sensing element.

JP 2020-077674 A discloses a semiconductor device including a semiconductor substrate provided with a drift region of first conductivity-type, a transistor part provided in the semiconductor substrate, a diode part provided in the semiconductor substrate, a well region of a second conductivity-type exposed on an top surface of the semiconductor substrate, a temperature detector being adjacent to the diode part in a top view and provided above the well region, and an top surface side lifetime control region provided on the top surface side of the semiconductor substrate in the diode part and in a region without overlapping with the temperature detector in the top view.

Semiconductor devices including a temperature detector such as a diode often cause slip around the temperature detector during heat treatment in a manufacturing process. The slip is crystal defects caused by sliding in crystals. The slip if caused has an influence on the properties of such a semiconductor device, decreasing a non-defect ratio accordingly.

### SUMMARY OF THE INVENTION

In view of the foregoing problems, the present invention provides a semiconductor device having a configuration capable of avoiding slip around a temperature detector.

In view of the foregoing problems, the present invention provides a semiconductor device including: a drift layer of a first conductivity-type; a base region of a second conductivity-type provided on a top surface side of the drift layer; a main region of the first conductivity-type provided on a top surface side of the base region; a first gate electrode buried in a first trench in contact with the main region and the base region with a gate insulating film interposed; a well region of the second conductivity-type provided on the top surface side of the drift layer; a temperature detector provided on a top surface side of the well region with an insulating film interposed; and a second gate electrode buried in a second trench provided in the well region and at least partly located immediately under the temperature detector with the gate insulating film interposed.

### BRIEF DESCRIPTION OF THE DRAWINGS

FIG. 1 is a schematic plan view illustrating an example of a semiconductor device according to a first embodiment;

FIG. 2 is a schematic enlarged plan view of region A in FIG. 1;

FIG. 3 is a cross-sectional view taken along line A-A′ in FIG. 2;

FIG. 4 is a cross-sectional view taken along line B-B′ in FIG. 2;

FIG. 5 is a cross-sectional view taken along line C-C′ in FIG. 2;

FIG. 6 is a schematic cross-sectional view for explaining an example of a method of manufacturing the semiconductor device according to the first embodiment;

FIG. 7 is a schematic cross-sectional view continued from FIG. 6 for explaining the example of the method of manufacturing the semiconductor device according to the first embodiment;

FIG. 8 is a schematic cross-sectional view continued from FIG. 7 for explaining the example of the method of manufacturing the semiconductor device according to the first embodiment;

FIG. 9 is a schematic cross-sectional view continued from FIG. 8 for explaining the example of the method of manufacturing the semiconductor device according to the first embodiment;

FIG. 10 is a schematic cross-sectional view continued from FIG. 9 for explaining the example of the method of manufacturing the semiconductor device according to the first embodiment;

FIG. 11 is a schematic cross-sectional view continued from FIG. 10 for explaining the example of the method of manufacturing the semiconductor device according to the first embodiment;

FIG. 12 is a schematic plan view illustrating a semiconductor device of a comparative example;

FIG. 13 is a cross-sectional view taken along line A-A′ in FIG. 12;

FIG. 14 is a cross-sectional view taken along line C-C′ in FIG. 12;

FIG. 15 is a schematic plan view illustrating an example of a semiconductor device according to a second embodiment;

FIG. 16 is a cross-sectional view taken along line A-A′ in FIG. 15;

FIG. 17 is a schematic plan view illustrating an example of a semiconductor device according to a third embodiment;

FIG. 18 is a schematic enlarged plan view of region A in FIG. 17;

FIG. 19 is a cross-sectional view taken along line A-A′ in FIG. 18;

FIG. 20 is a schematic plan view illustrating an example of a semiconductor device according to a fourth embodiment; and

FIG. 21 is a schematic plan view illustrating an example of a semiconductor device according to a fifth embodiment.

### DETAILED DESCRIPTION

With reference to the drawings, first to fifth embodiments of the present invention will be described below.

In the drawings, the same or similar elements are indicated by the same or similar reference numerals, and overlapping explanations are not repeated. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first to fifth embodiments described below merely illustrate schematically devices and methods for specifying and giving shapes to the technical idea of the present invention, and the span of the technical idea is not limited to materials, shapes, structures, and relative positions of elements described herein.

As used in the present specification, an emitter region of an insulated gate bipolar transistor (IGBT) is referred to as “one of the main regions (a first main region)” that can be used as a source region of a metal-oxide-semiconductor field-effect transistor (MOSFET). The “one of the main regions”, when provided in a thyristor such as a MOS controlled static induction thyristor (SI thyristor), can be used as a cathode region. A collector region in the IGBT is referred to as the “other one of the main regions (a second main region)” of the semiconductor device that can be used as a drain region of the MOSFET or as an anode region in the thyristor. The term “main region”, when simply mentioned in the present specification, is referred to as either the first main region or the second main region that is determined as appropriate by the person skilled in the art.

Further, definitions of directions such as an up-and-down direction in the following description are merely definitions for convenience of understanding, and are not intended to limit the technical ideas of the present invention. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction. In addition, a “top surface” may be read as “front surface”, and a “bottom surface” may be read as “back surface”.

Further, in the following description, there is exemplified a case where a first conductivity-type is an n-type and a second conductivity-type is a p-type. However, the relationship of the conductivity types may be inverted to set the first conductivity-type to the p-type and the second conductivity-type to the n-type. Further, a semiconductor region denoted by the symbol “n” or “p” attached with “+” indicates that such semiconductor region has a relatively high impurity concentration or a relatively low specific resistance as compared to a semiconductor region denoted by the symbol “n” or “p” without “+”. A semiconductor region denoted by the symbol “n” or “p” attached with “−” indicates that such semiconductor region has a relatively low impurity concentration or a relatively high specific resistance as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration or the same specific resistance.

### First Embodiment

### <Structure of Semiconductor Device>

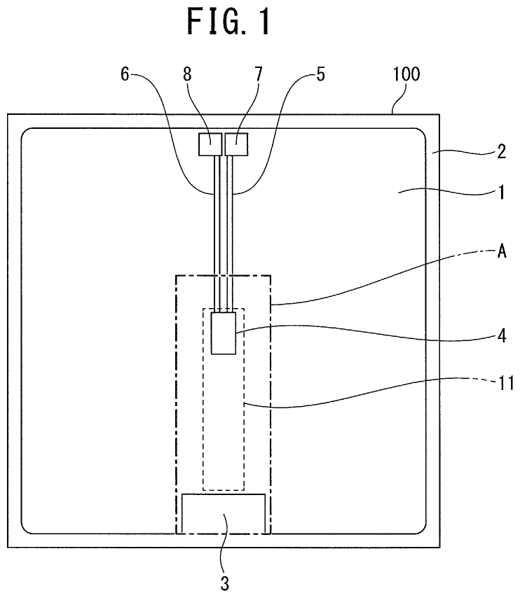

A semiconductor device according to a first embodiment includes an active region 1 provided in a semiconductor substrate 100, and an edge termination region (a voltage blocking region) 2 provided in the semiconductor substrate 100 so as to surround the circumference of the active region 1, as illustrated in FIG. 1.

The semiconductor substrate 100 is a semiconductor chip that is a diced piece of a semiconductor wafer having a diameter in a range of about 200 millimeters or greater and 300 millimeters or smaller, for example. The diameter of the semiconductor wafer may be about 300 millimeters or greater. The semiconductor substrate 100 is a silicon (Si) substrate, for example. The semiconductor substrate 100 is not limited to the Si substrate, and may be another semiconductor substrate including a semiconductor (a wide band-gap semiconductor) having a wider band gap than Si, such as silicon carbide (SIC), gallium nitride (GaN), gallium oxide (Ga₂O₃), diamond (C), or aluminum nitride (AlN), for example.

The active region 1 includes an active element. The semiconductor device according to the first embodiment is illustrated with a case of including an IGBT having a trench gate structure as the active element. The edge termination region 2 relaxes an electric-field concentration on the top surface side of the semiconductor substrate 100.

The active region 1 has a substantially rectangular planar pattern. The active region 1 is provided in the middle with a temperature detector 4. The semiconductor device according to the first embodiment is illustrated with a case in which the temperature detector 4 is a p-n junction diode (a temperature-detecting diode) including semiconductor material such as polysilicon. A first pad (an anode pad) 7 and a second pad (a cathode pad) 8 are arranged at the outer circumference of the active region 1. The anode pad 7 is electrically connected to an anode side of the temperature detector 4 via a wire 5 made from material such as metal or polysilicon. The cathode pad 8 is electrically connected to a cathode side of the temperature detector 4 via a wire 6 made from material such as metal or polysilicon.

A gate pad 3 is provided on the opposite side of the anode pad 7 and the cathode pad 8 at the outer circumference of the active region 1. The gate pad 3 is electrically connected to a gate of the IGBT of the active region 1 via a gate runner (not illustrated) connected to the gate pad 3.

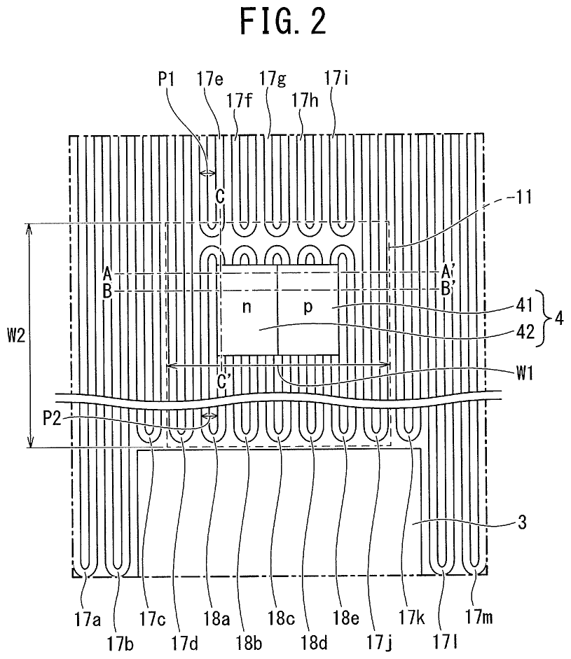

FIG. 2 is an enlarged plan view of region A including the temperature detector 4 and the gate pad 3 indicated by the dash-dotted line illustrated in FIG. 1. FIG. 2 omits the illustration of the respective wires 5 and 6 connected to the temperature detector 4 illustrated in FIG. 1. As illustrated in FIG. 2, the semiconductor device according to the first embodiment includes trenches (first trenches) 17a to 17m arranged at the circumference of the temperature detector 4 without overlapping with the temperature detector 4 in the planar view, and trenches (second trenches) 18a to 18e arranged to at least partly overlap with the temperature detector 4.

The respective trenches 17a to 17m have an O-shaped planar pattern. The trenches 17a to 17m each include a pair of straight stripe parts extending into a striped state in one direction, which is the upper-lower direction in FIG. 2 and is herein referred to also as a “first direction”. The stripe parts of the respective trenches 17a to 17m have substantially the same width. The stripe parts of the respective trenches 17a to 17m have substantially the same pitch P1 in the direction perpendicular to the first direction, which is the right-left direction in FIG. 2 and is herein referred to also as a “second direction”.

The respective end parts of the trenches 17a, 17b, 17l, and 17m in the first direction (the upper-lower direction in FIG. 2) located on the outermost side in FIG. 2 are located adjacent to the outer circumference of the active region 1. The respective end parts of the trenches 17c, 17d, 17j, and 17k in the first direction (the upper-lower direction in FIG. 2) located on the inner side of the trenches 17a, 17b, 17l, and 17m (toward the center) are opposed to the gate pad 3. The respective end parts of the trenches 17e to 17i in the first direction (the upper-lower direction in FIG. 2) located on the inner side of the trenches 17c, 17d, 17j, and 17k (toward the center) are opposed to the end parts of the respective trenches 18a to 18e.

The outline of the region provided with the trenches 18a to 18e has a substantially rectangular planar pattern. One end of the respective trenches 18a to 18e in the first direction (the upper-lower direction in FIG. 2) is opposed to the gate pad 3. The other end of the respective trenches 18a to 18e is opposed to the end part of the respective trenches 17e to 17i. The respective trenches 18a to 18e have an O-shaped planar pattern. The trenches 18a to 18e each include a pair of straight stripe parts extending into a striped state in the first direction (the upper-lower direction in FIG. 2).

The stripe parts of the trenches 18a to 18e are aligned with the stripe parts of the trenches 17e to 17i respectively at substantially the same positions in the first direction (the upper-lower direction in FIG. 2). The stripe parts of the trenches 18a to 18e are not necessarily aligned with the stripe parts of the trenches 17e to 17i, and may be displaced from each other.

The respective stripe parts of the trenches 18a to 18e have substantially the same width. The width of the stripe parts of the trenches 18a to 18e is substantially the same as that of the stripe parts of the trenches 17a to 17m. The width of the stripe parts of the trenches 18a to 18e is not necessarily common to that of the stripe parts of the trenches 17a to 17m.

The respective stripe parts of the trenches 18a to 18e have substantially the same pitch P2 in the second direction (the right-left direction in FIG. 2). The pitch P2 of the stripe parts of the respective trenches 18a to 18e is substantially the same as the pitch P1 of the stripe parts of the respective trenches 17a to 17m. The pitch P2 of the stripe parts of the respective trenches 18a to 18e may be different from the pitch P1 of the stripe parts of the respective trenches 17a to 17m. For example, the pitch P2 of the stripe parts of the respective trenches 18a to 18e may be about half or greater and two times or smaller of the pitch P1 of the stripe parts of the respective trenches 17a to 17m. The number of the trenches 18a to 18e arranged to overlap with the temperature detector 4 is not limited to the case as illustrated, and may be changed as appropriate depending on the number, the width, and the pitch P1 of the trenches 17a to 17m, the size of the temperature detector 4, and the size of a well region 11 described below, for example.

The planar pattern of the respective trenches 17a to 17m and 18a to 18e is not limited to the O-like shape. For example, the trenches 17a to 17m and the trenches 18a to 18e may each have an I-shaped or U-shaped planar pattern including stripe parts extending in the first direction (the upper-lower direction in FIG. 2). Alternatively, the trenches 17a to 17m and the trenches 18a to 18e may have planar patterns different from each other. For example, either the trenches 17a to 17m or the trenches 18a to 18e may have the O-shaped planar pattern, and the other ones may have the I-shaped planar pattern.

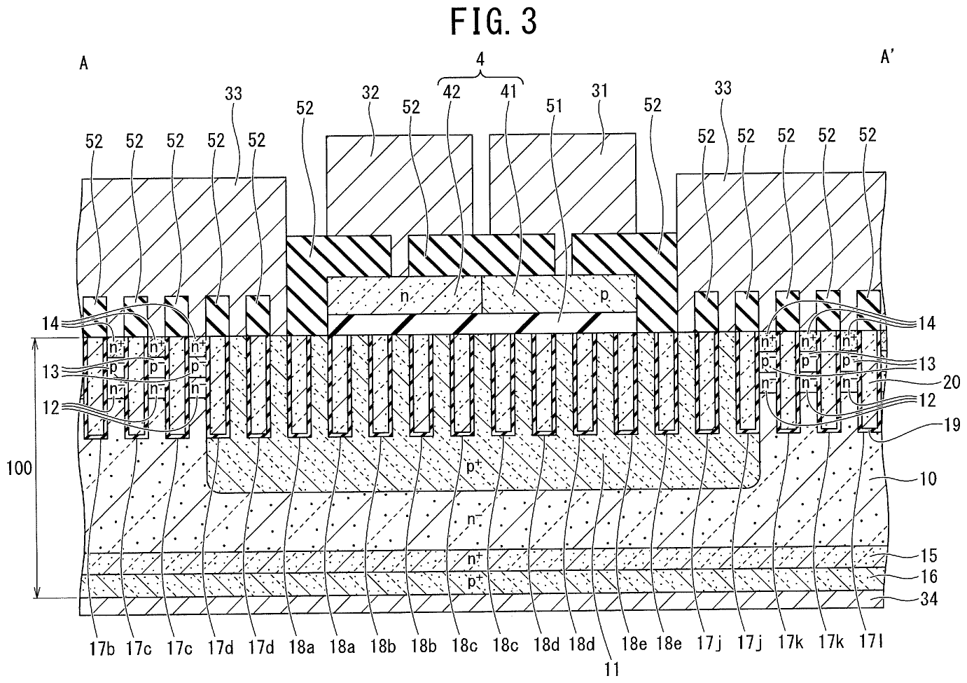

FIG. 3 is a cross-sectional view taken along line A-A′ passing across the temperature detector 4, the trenches 17b to 17d and 17j to 17l, and the trenches 18a to 18e in the second direction in FIG. 2 (the right-left direction in FIG. 2). As illustrated in FIG. 3, the semiconductor substrate 100 includes a drift layer 10 of a first conductivity-type (n⁻-type). An accumulation layer 12 of the first conductivity-type (n⁻-type) having a higher impurity concentration than the drift layer 10 is provided on the top surface side of the drift layer 10 at the position on the outside of the temperature detector 4. The bottom surface of the accumulation layer 12 is in contact with the top surface of the drift layer 10.

A base region 13 of a second conductivity-type (p⁻-type) is provided on the top surface side of the accumulation layer 12. The bottom surface of the base region 13 is in contact with the top surface of the accumulation layer 12. The semiconductor substrate 100 does not necessarily include the accumulation layer 12. The bottom surface of the base region 13 may be in contact with the top surface of the drift layer 10 when the accumulation layer 12 is not provided. A first main region (an emitter region) 14 of the first conductivity-type (n⁺-type) having a higher impurity concentration than the drift layer 10 is provided on the top surface side of the base region 13.

The well region 11 that is a diffusion layer of the second conductivity-type (p⁺-type) is deposited at the upper part (on the top surface side) of the drift layer 10 located under the temperature detector 4. The well region 11 is provided to improve a breakdown voltage and also improve destruction immunity.

The temperature detector (the temperature-detecting diode) 4 is provided on the top surface side of the well region 11 with an insulating film (a field insulating film) 51 interposed. The field insulating film 51 is made of an insulating film such as an oxide film, for example.

The temperature detector 4 includes an anode region 41 of p-type and a cathode region 42 of n-type arranged in contact with the anode region 41. The anode region 41 and the cathode region 42 each include polysilicon, for example. The temperature detector 4 does not necessarily have this configuration, and may include plural pairs of the anode region 41 and the cathode region 42 implementing the p-n junction so that the respective pairs of the anode region 41 and the cathode region 42 are connected either in series or in parallel.

An insulating film (an interlayer insulating film) 52 is deposited to cover the anode region 41 and the cathode region 42. The interlayer insulating film 52 is a borophosphosilicate glass film (a BPSG film), for example. Other examples include a phosphosilicate glass film (a PSG film), a non-doped silicon oxide film without including phosphorus (P) or boron (B) which is referred to as a non-doped silicate glass (NSG) film, a borosilicate glass film (a BSG film), and a silicon nitride film (a Si₃N₄ film). The interlayer insulating film 52 may be a stacked-layer film including the above films stacked on one another.

An anode electrode 31 and a cathode electrode 32 are provided on the top surface side of the anode region 41 and the cathode region 42 with the interlayer insulating film 52 interposed. The anode electrode 31 is electrically connected to the anode region 41 through contact holes provided in the interlayer insulating film 52 located on the top surface side of the anode region 41. The anode electrode 31 corresponds to the wire 5 illustrated in FIG. 1, and is electrically connected to the anode pad 7. The cathode electrode 32 is electrically connected to the cathode region 42 through contact holes provided in the interlayer insulating film 52 located on the top surface side of the cathode region 42. The cathode electrode 32 corresponds to the wire 6 illustrated in FIG. 1, and is electrically connected to the cathode pad 8.

FIG. 1 and FIG. 2 each schematically indicate the planar pattern of the well region 11 by the broken line. As illustrated in FIG. 1 and FIG. 2, the well region 11 has a substantially rectangular planar pattern. The well region 11 extends in the longitudinal direction that is the first direction (the upper-lower direction in FIG. 1 and FIG. 2). As illustrated in FIG. 2, a width W1 of the well region 11 in the second direction (the right-left direction in FIG. 2) is in a range of about 100 micrometers or greater and 500 micrometers or smaller, and may be in a range of about 200 micrometers or greater and 300 micrometers or smaller, for example. A width W2 of the well region 11 in the first direction (the upper-lower direction in FIG. 2) is greater than the width W1, and is in a range of about 100 micrometers or greater and 20 millimeters or smaller, which is 10 times or greater and 100 times or smaller of the width W1, for example.

One end of the well region 11 in the first direction (the upper-lower direction in FIG. 2) is located adjacent to the gate pad 3, and the other end is located adjacent to the temperature detector 4. The well region 11 is provided in a wider range than the temperature detector 4 in the planar view. The temperature detector 4 is arranged inside the well region 11 so as to entirely overlap with the well region 11.

As illustrated in FIG. 3, the trenches 17b to 17d and 17j to 17l and the trenches 18a to 18e are dug from the top surface of the semiconductor substrate 100 in the depth direction vertical to the top surface of the semiconductor substrate 100. The trenches 17b to 17d and 17j to 17l and the trenches 18a to 18e each have a width of about one micrometer, for example. The trenches 17b to 17d and 17j to 17l and the trenches 18a to 18e each have a depth in a range of about three micrometers or greater and ten micrometers or smaller, and may be in a range of five micrometers or greater and six micrometers or smaller, for example. The depth of the trenches 17b to 17d and 17j to 17l and the trenches 18a to 18e is shallower than the depth of the well region 11. The trenches 17a, 17e to 17i, and 17m illustrated in FIG. 2 each also have the same configuration as the trenches 17b to 17d and 17j to 17l illustrated in FIG. 3.

As illustrated in FIG. 3, the trenches 17b to 17d and 17j to 17l penetrate the emitter region 14, the base region 13, and the accumulation layer 12 to reach the drift layer 10. The trenches 17b to 17d and 17j to 17l are each a gate trench of the IGBT having a trench gate structure serving as the active element included in the active region 1. The emitter region 14, the base region 13, and the accumulation layer 12 are in contact with the side walls (the side surfaces) of the trenches 17b to 17d and 17j to 17l. The emitter region 14, the base region 13, and the accumulation layer 12 are located in mesa parts of the semiconductor substrate 100 interposed between the respective trenches 17b to 17d and 17j to 17l next to each other. The trenches 17d and 17j of the trenches 17b to 17d and 17j to 17l located on the innermost side are arranged in the well region 11.

The trenches 18a to 18e are located in the well region 11. The side walls (the side surfaces) and the bottom surfaces of the trenches 18a to 18e are in contact with the well region 11, but are not in contact with the emitter region 14, the base region 13, or the accumulation layer 12. The trenches 18a to 18e each serve as a dummy trench.

As illustrated in FIG. 2, the trenches 17a to 17c and 17k to 17m are located at the positions not overlapping with the well region 11 in the planar view. The trenches 17d to 17j are located to partly overlap with the well region 11. The trenches 18a to 18e are located to overlap with the well region 11.

As illustrated in FIG. 3, a gate electrode 20 is buried inside the respective trenches 17b to 17d and 17j to 17l and the respective trenches 18a to 18e with a gate insulating film 19 interposed. The gate insulating film 19 and the gate electrode 20 implement an insulated gate electrode structure (19, 20). A gate potential is applied, from the gate pad 3 through a gate runner (not illustrated), to the gate electrode 20 buried in the respective trenches 17b to 17d and 17j to 17l with the gate insulating film 19 interposed.

The gate electrode 20 buried in the respective trenches 18a to 18e with the gate insulating film 19 interposed serves as a dummy electrode to have a floating potential while not being electrically connected to the gate pad 3. The gate electrode 20 buried in the respective trenches 18a to 18e with the gate insulating film 19 interposed may be electrically connected to an emitter electrode 33 through contact holes provided in the interlayer insulating film 52. In such a case, an emitter potential is applied through the emitter electrode 33 to the gate electrode 20 buried in the respective trenches 18a to 18e with the gate insulating film 19 interposed so as to have the same potential as the emitter region 14.

The gate insulating film 19 as used herein can be a silicon oxide film (a SiO₂ film), or a single film of any of a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, or a bismuth oxide (Bi₂O₃) film, or a composite film including some of the above films stacked on one another. The gate electrode 20 can be made of a polysilicon layer (a doped polysilicon layer) heavily doped with impurity ions such as phosphorus (P) or boron (B), for example.

The front-surface electrode (the emitter electrode) 33 is located on the top surface side of the emitter region 14 with the interlayer insulating film 52 interposed. The emitter electrode 33 is electrically connected to the emitter region 14 through the contact holes provided in the interlayer insulating film 52 located on the top surface side of the emitter region 14. The emitter electrode 33 may include metal such as aluminum (Al), an Al alloy, or copper (Cu). Examples of Al alloys include an Al-silicon (Si) alloy, an Al—Si—Cu alloy, and Al—Cu alloy. The emitter electrode 33 may be provided with plugs including tungsten (W) or the like inside the contact holes, and may be provided with a barrier metal layer made of material such as titanium (Ti) or titanium nitride (TiN) between the respective plugs and the emitter region 14. The anode electrode 31 and the cathode electrode 32 may include the same material as the emitter electrode 33.

The well region 11 located in the mesa parts of the semiconductor substrate 100 interposed between the respective trenches 17d and 17j and the respective trenches 18a and 18e is electrically connected to the emitter electrode 33 through the contact holes provided in the interlayer insulating film 52 located on the top surface side of the well region 11. The emitter potential is applied to the well region 11 through the emitter electrode 33 so as to have the same potential as the emitter region 14. The interlayer insulating film 52 located on the top surface side of the well region 11 is not necessarily provided with the contact holes, and the well region 11 may have a floating potential instead.

As illustrated in FIG. 3, a buffer layer 15 of the first conductivity-type (n⁺-type) having a higher impurity concentration than the drift layer 10 is deposited on the bottom surface side of the drift layer 10. The present embodiment does not necessarily include the buffer layer 15. A second main region (a collector region) 16 of the second conductivity-type (p⁺-type) is provided on the bottom surface side of the buffer layer 15.

A rear-surface electrode (a collector electrode) 34 is deposited on the bottom surface side of the collector region 16. The collector electrode 34 can be a single-layer film including gold (Au), or a metallic film including titanium (Ti), nickel (Ni), and Au stacked in this order, and may be further provided with a metallic film including molybdenum (Mo) or tungsten (W) as the lowermost layer, for example. A contact layer such as a nickel silicide (NiSiₓ) layer may be provided between the collector region 16 and the collector electrode 34.

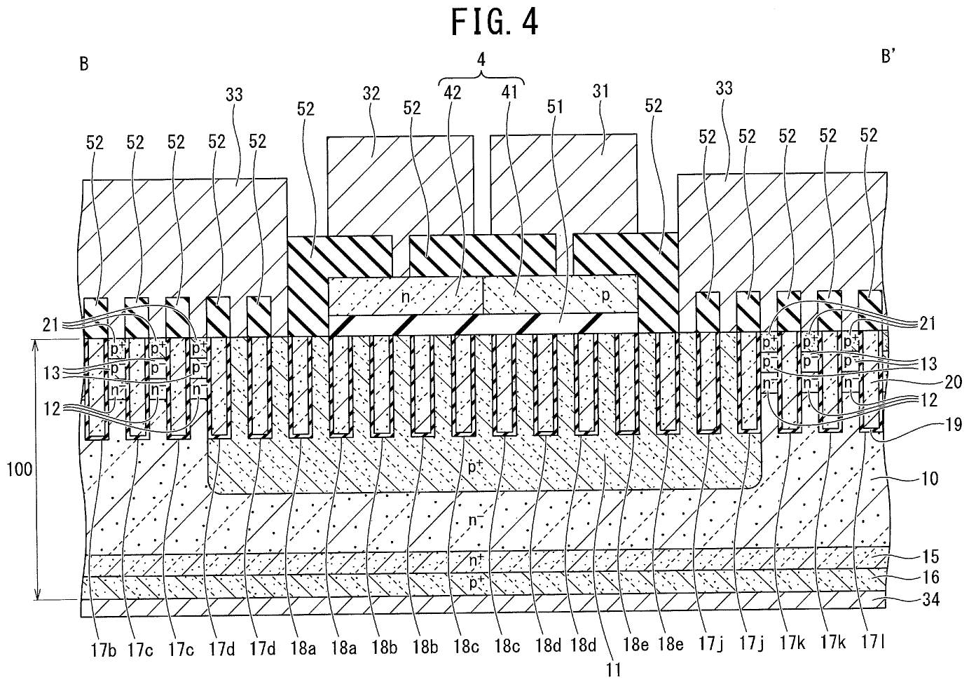

FIG. 4 is a cross-sectional view taken along line B-B′ parallel to line A-A′ in FIG. 2. The cross section illustrated in FIG. 4 differs from the cross section illustrated in FIG. 3 in that a contact region 21 of p⁺-type having a higher impurity concentration than the base region 13 is provided on the top surface side of the base region 13. The contact region 21 illustrated in FIG. 4 and the emitter region 14 illustrated in FIG. 3 are in contact with each other, and are alternately and periodically provided in the first direction, which is a direction from the front side to the back side of the sheet in FIG. 3 and FIG. 4.

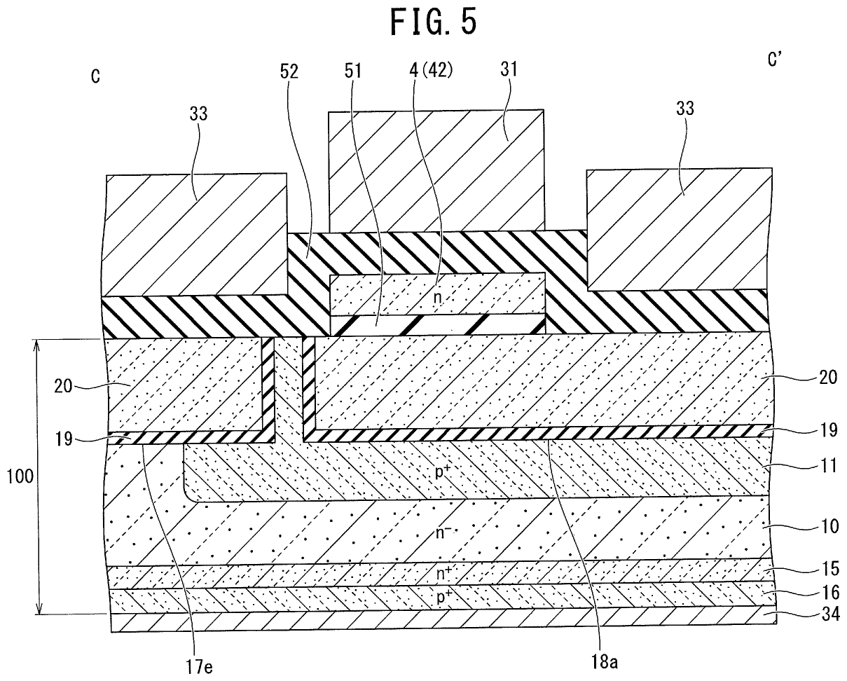

FIG. 5 is a cross-sectional view taken along line C-C′ passing across the temperature detector 4, the trench 17e, and the trench 18a in the first direction in FIG. 2 (the upper-lower direction in FIG. 2). As illustrated in FIG. 5, the p⁺-type well region 11 is provided at the upper part of the semiconductor substrate 100. A part of the trench 17e is located inside the well region 11. The trench 18a is located inside the well region 11. The end part of the trench 18a is opposed to the end part of the trench 17e. A part of the trench 18a is located immediately under the temperature detector 4.

The semiconductor device according to the first embodiment during the operation of the IGBT included in the active region 1 applies a positive voltage to the collector electrode 34 through the emitter electrode 33 as a ground potential, and causes an inversion layer (a channel) to be formed in the base region 13 toward the side surfaces of the respective trenches 17a to 17m so as to be turned ON when a positive voltage of a threshold or greater is applied to the gate electrode 20 buried in the respective trenches 17a to 17m with the gate insulating film 19 interposed. In the ON-state, a current flows from the collector electrode 34 toward the emitter electrode 33 through the collector region 16, the buffer layer 15, the drift layer 10, the accumulation layer 12, the inversion layers in the base region 13, and the emitter region 14. When the voltage applied to the gate electrode 20 buried in the respective trenches 17a to 17m with the gate insulating film 19 interposed is smaller than the threshold, the semiconductor device is led to be in the OFF-state since no inversion layer is formed in the base region 13, and no current flows from the emitter electrode 33 from the collector electrode 34.

### <Method of Manufacturing Semiconductor Device>

An example of a method of manufacturing the semiconductor device according to the first embodiment is described below basically with reference to the cross section illustrated in FIG. 3. It should be understood that the method of manufacturing the semiconductor device described below is an example, and the semiconductor device can be manufactured by other methods including modified examples of this embodiment within the scope of the appended claims.

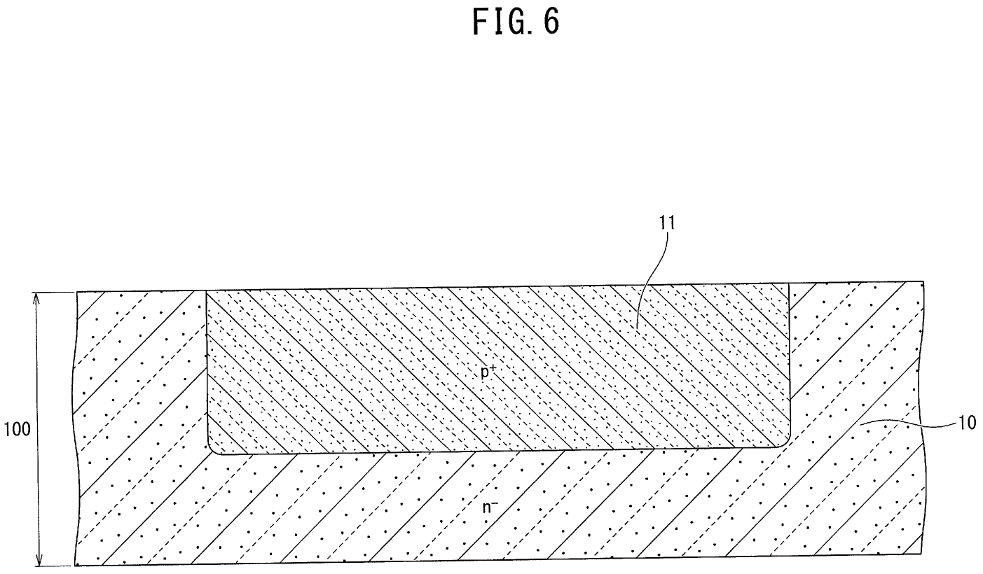

First, the semiconductor substrate 100 that is a semiconductor wafer such as a silicon (Si) wafer having a diameter of about 300 millimeters for forming the drift layer 10 of the first conductivity-type (n⁻-type) is prepared (refer to FIG. 6). A photoresist film is then applied to the top surface of the semiconductor substrate 100, and is delineated by photolithography. Using the delineated photoresist film as a mask for ion implantation, p-type impurity ions such as boron (B) are implanted to the top surface of the drift layer 10. The photoresist film used as the mask for ion implantation is then removed. This step forms the p⁺-type well region 11 on the top surface side (at the upper part) of the semiconductor substrate 100, as illustrated in FIG. 6.

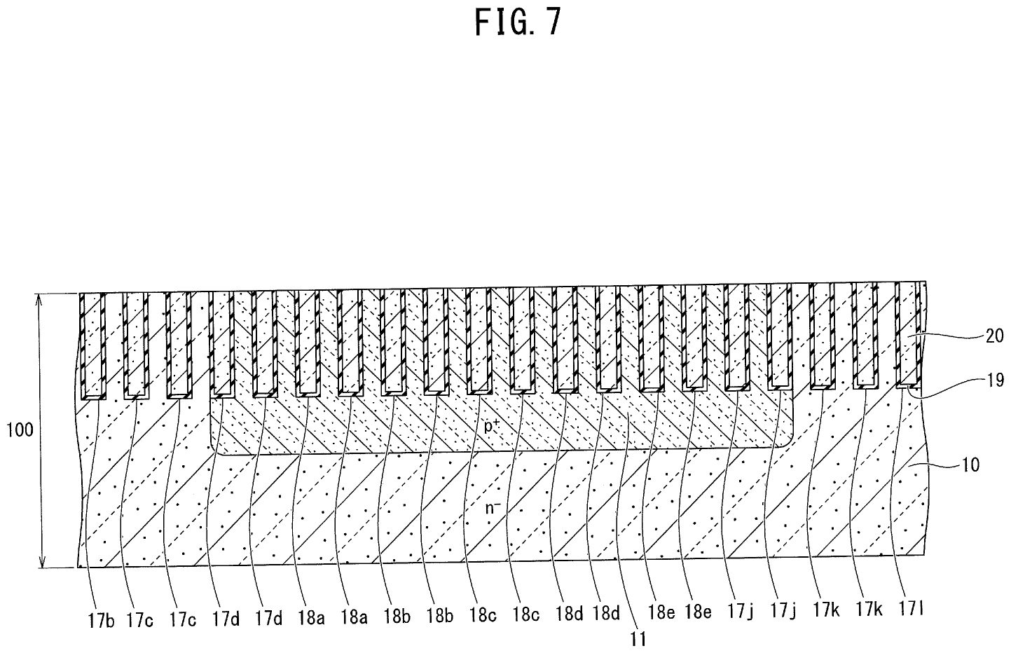

Next, a part of the semiconductor substrate 100 is selectively removed from the top surface side in the depth direction by photolithography and dry etching so as to dig down the trenches 17b to 17d and 17j to 17l and the trenches 18a to 18e (refer to FIG. 7). The trenches 17b, 17c, 17k, and 17l are formed on the outside of the well region 11, while the trenches 17d and 17j and the trenches 18a to 18e are formed on the inside of the well region 11.

Next, the gate insulating film 19 (refer to FIG. 7) is formed on the bottom surfaces and the side surfaces of the trenches 17b to 17d and 17j to 17l and the trenches 18a to 18e by thermal oxidation, chemical vapor deposition (CVD), or the like. A polysilicon film (a doped polysilicon film) heavily doped with impurity ions such as phosphorus (P) or boron (B) is deposited so as to fill the inside of the trenches 17b to 17d and 17j to 17l and the trenches 18a to 18e with the gate insulating film 19 interposed by CVD or the like. The polysilicon film and the gate insulating film 19 on the top surface side of the semiconductor substrate 100 are then etch-backed. This step buries the gate electrode 20 inside the respective trenches 17b to 17d and 17j to 17l and the trenches 18a to 18e with the gate insulating film 19 interposed, as illustrated in FIG. 7.

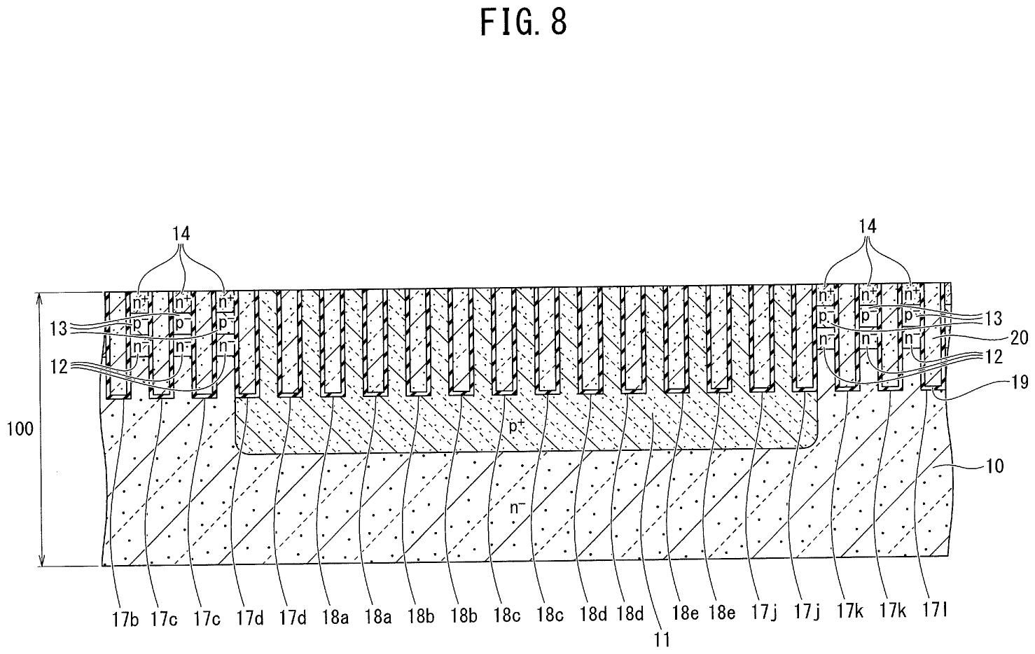

Next, the n⁻-type accumulation layer 12, the p⁻-type base region 13, the n⁺-type emitter region 14, and the p⁺-type contact region 21 are sequentially formed at the upper part (on the top surface side) of the semiconductor substrate 100 by photolithography and ion implantation, as illustrated in FIG. 8. The heat treatment (annealing) is then executed at a temperature in a range of about 800° C. or higher and 1150° C. or lower, for example, so as to activate the p-type impurity ions and the n-type impurity ions implanted into the semiconductor substrate 100.

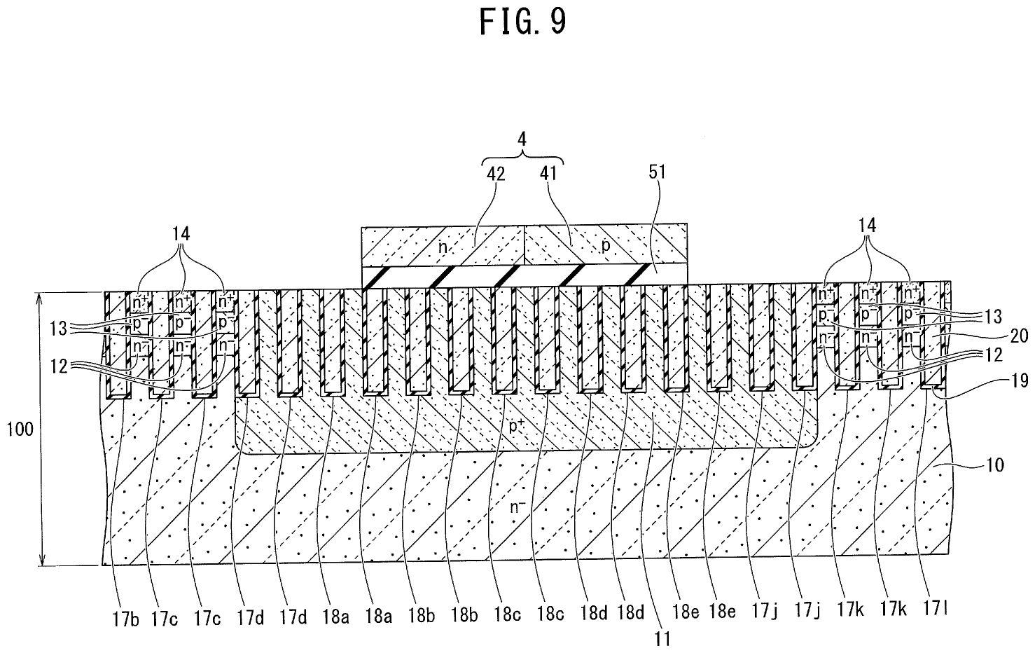

Next, the insulating film 51 and the polysilicon film are sequentially deposited on the top surface side of the semiconductor substrate 100 by CVD or the like. Next, the p-type anode region 41 and the n-type cathode region 42 (refer to FIG. 9) are formed in the polysilicon film located on the top surface side of the well region 11 by photolithography and ion implantation. Next, the insulating film 51 and the polysilicon film are partly and selectively removed by photolithography and dry etching. This step provides the temperature detector 4 including the anode region 41 and the cathode region 42 on the top surface side of the well region 11 with the insulating film 51 interposed, as illustrated in FIG. 9.

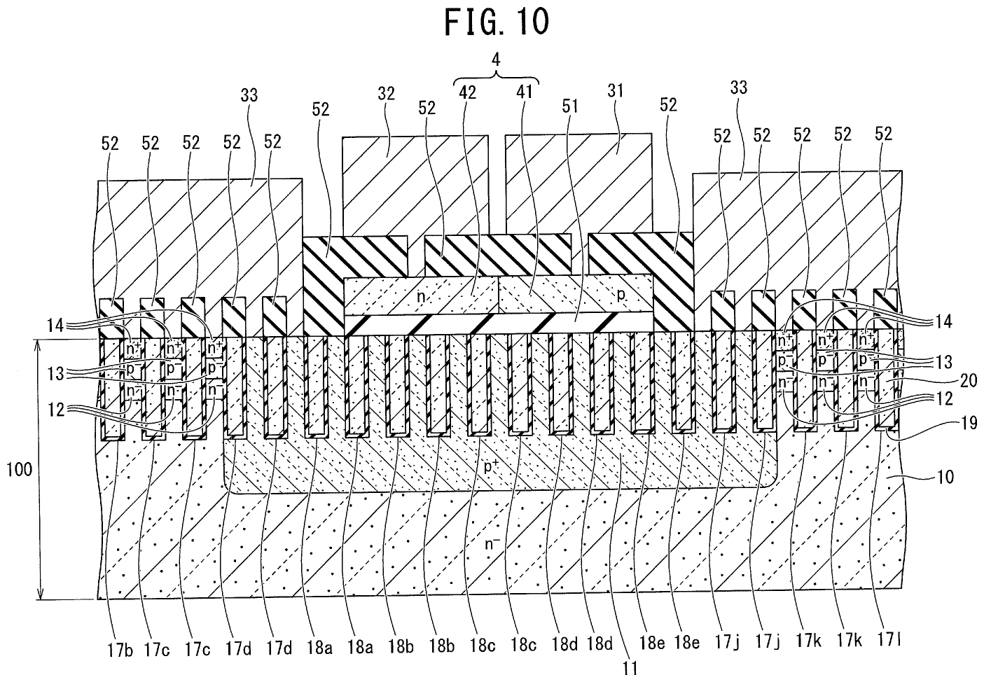

Next, the insulating film 52 is deposited on the top surface side of the semiconductor substrate 100 by CVD or the like. Next, the contact holes are opened in the insulating film 52 by photolithography and dry etching. Next, a metallic film is deposited on the top surface side of the insulating film 52 by sputtering, vapor deposition, or the like. A part of the metallic film is then selectively removed by photolithography and dry etching so as to form the anode electrode 31, the cathode electrode 32, and the emitter electrode 33 on the top surface side of the insulating film 51, as illustrated in FIG. 10.

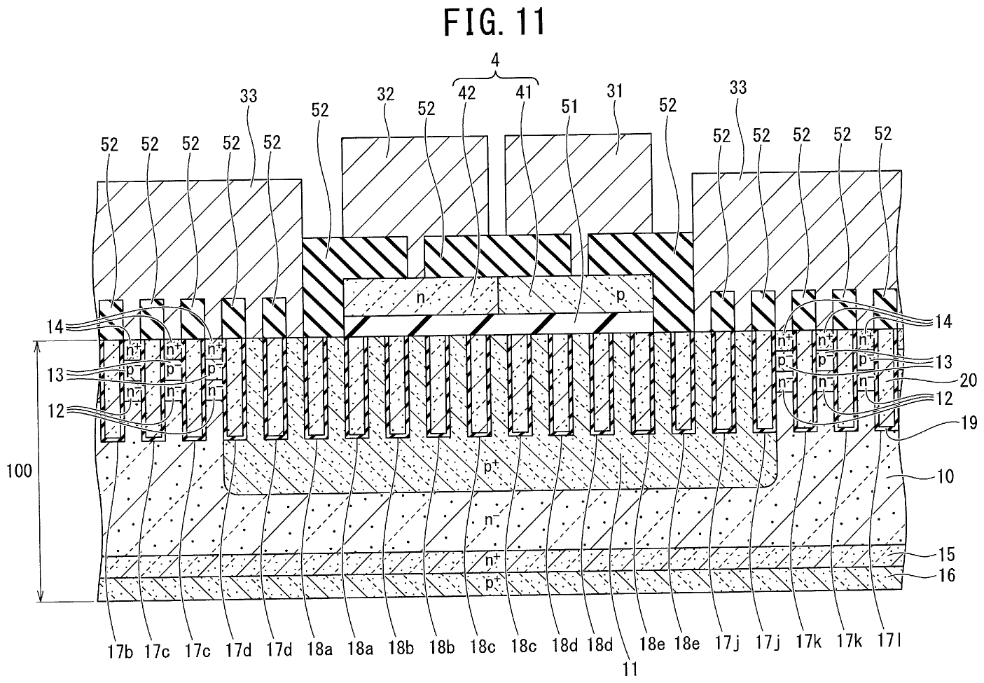

Next, the semiconductor substrate 100 is ground from the bottom surface side so as to adjust the thickness of the semiconductor substrate 100 as necessary. Next, the n⁺-type buffer layer 15 and the p⁺-type collector region 16 are sequentially formed on the bottom surface side of the semiconductor substrate 100 by photolithography and ion implantation, as illustrated in FIG. 11. Next, the collector electrode 34 (refer to FIG. 3) is formed on the bottom surface side of the collector region 16 by sputtering, vapor deposition, or the like. The semiconductor substrate 100 of the semiconductor wafer is then diced into a plurality of semiconductor chips. The semiconductor device according to the first embodiment is thus completed.

### Comparative Example

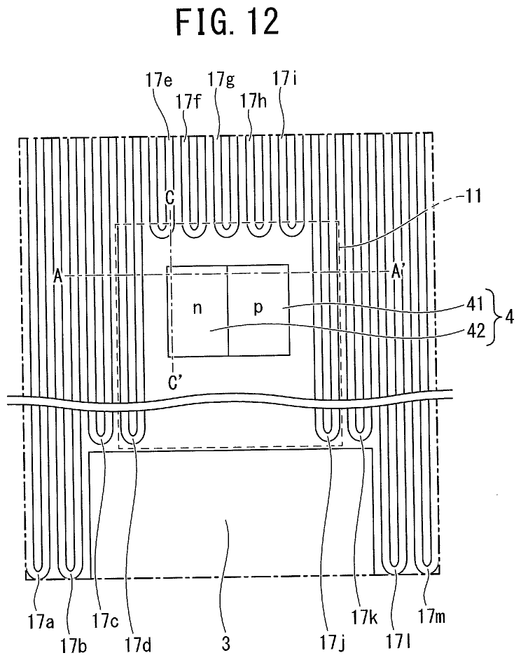

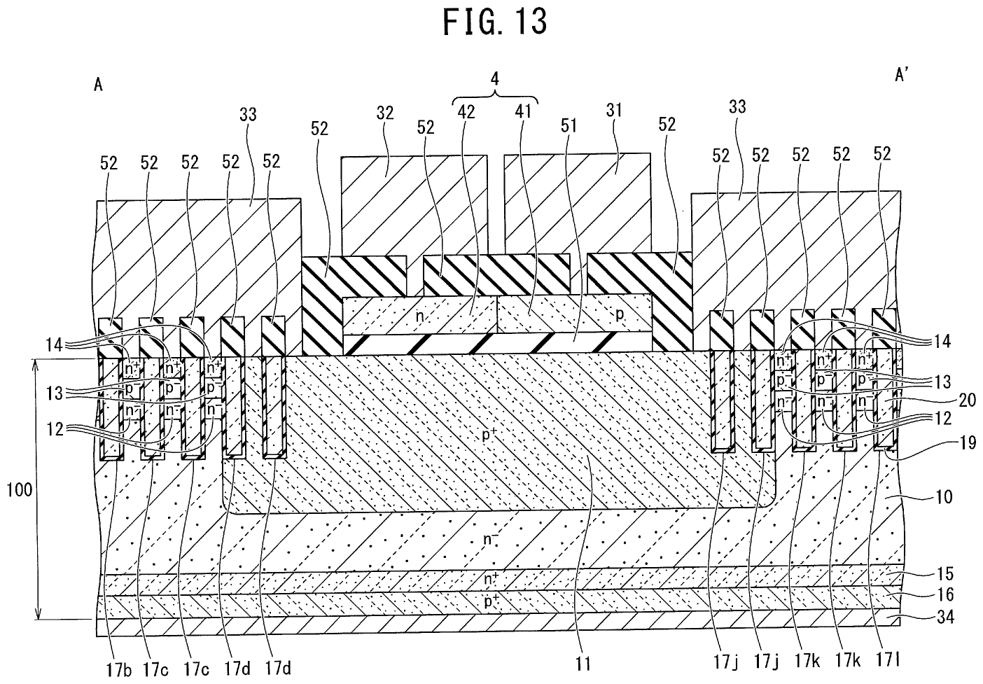

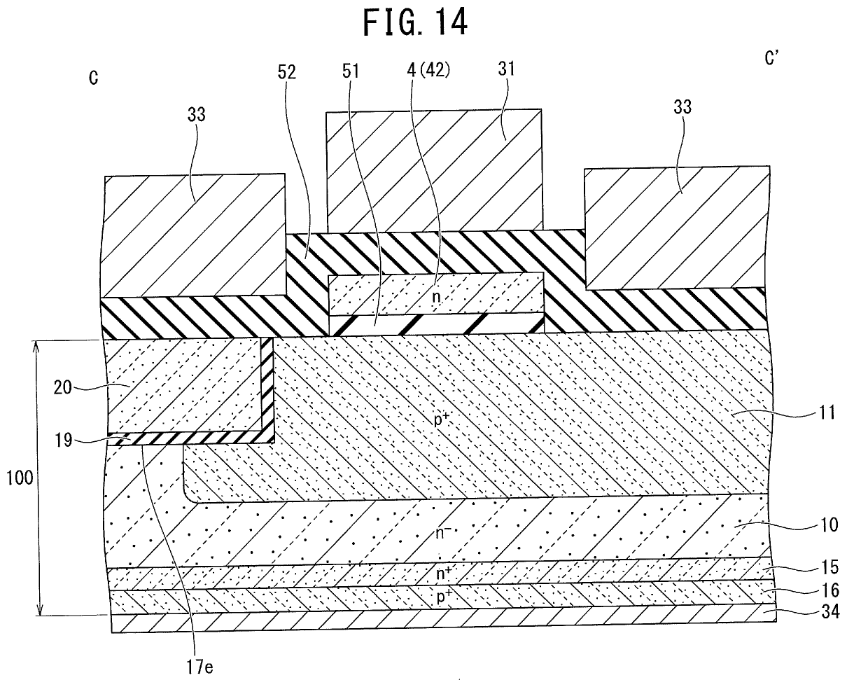

A semiconductor device of a comparative example is described below. FIG. 12 is a plan view illustrating the semiconductor device of the comparative example, and corresponds to the plan view of the semiconductor device according to the first embodiment illustrated in FIG. 2. FIG. 13 is a cross-sectional view taken along line A-A′ in FIG. 12, and corresponds to the cross-sectional view of the semiconductor device according to the first embodiment illustrated in FIG. 3. FIG. 14 is a cross-sectional view taken along line C-C′ in FIG. 12, and corresponds to the cross-sectional view of the semiconductor device according to the first embodiment illustrated in FIG. 5.

As illustrated in FIG. 12 to FIG. 14, the semiconductor device of the comparative example differs from the semiconductor device according to the first embodiment in not including the trenches 18a to 18e. The semiconductor device of the comparative example would cause slip in the well region 11 located under the temperature detector 4 during heat treatment (annealing) in the manufacturing process.

The increase in size of the semiconductor wafer implementing the semiconductor substrate 100 inevitably increases its weight, leading to a remarkable cause of slip. For example, the semiconductor wafer, when having a diameter of about 300 millimeters and provided with the trenches 17a to 17m with a depth in a range of about five micrometers or greater and six micrometers or smaller, and when subjected to heat treatment at a temperature of about 800° C. or higher and 1150° C. or lower, can cause slip to decrease a non-defect ratio. The reason for this is presumed that the width of the well region 11 in the second direction (the right-left direction in FIG. 12 and FIG. 13) is as narrow as 300 micrometers or smaller, which applies a stress on the region not provided with the trenches during the heat treatment. If the width of the well region 11 not provided with the trenches is increased, the area of the active region 1 is decreased, deteriorating the properties accordingly.

In contrast, the semiconductor device according to the first embodiment, which includes the trenches 18a to 18e provided inside the well region 11 located under the temperature detector 4, can eliminate particular points not provided with the trenches in the semiconductor substrate 100, so as to prevent a stress concentration on the well region 11, avoiding a cause of slip around the temperature detector 4 during the heat treatment accordingly.

### Second Embodiment

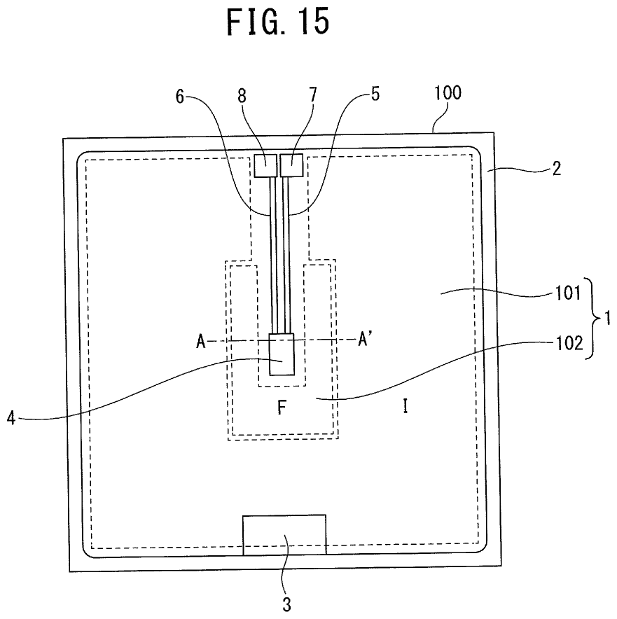

A semiconductor device according to a second embodiment differs from the semiconductor device according to the first embodiment in that the active region 1 is implemented by a reverse-conducting insulated gate bipolar transistor (RC-IGBT), as illustrated in FIG. 15.

The active region 1 includes a transistor part 101 provided at the circumference of the temperature detector 4, and a diode part 102 arranged between the temperature detector 4 and the transistor part 101. FIG. 15 indicates the transistor part 101 by sign “I” and the diode part 102 by sign “F”. The transistor part 101 includes the IGBT as an active element. The diode part 102 includes a freewheeling diode (FWD) as a diode connected antiparallel to the IGBT. The arranged positions of the transistor part 101 and the diode part 102 are not limited to the case as illustrated, and can be changed as appropriate.

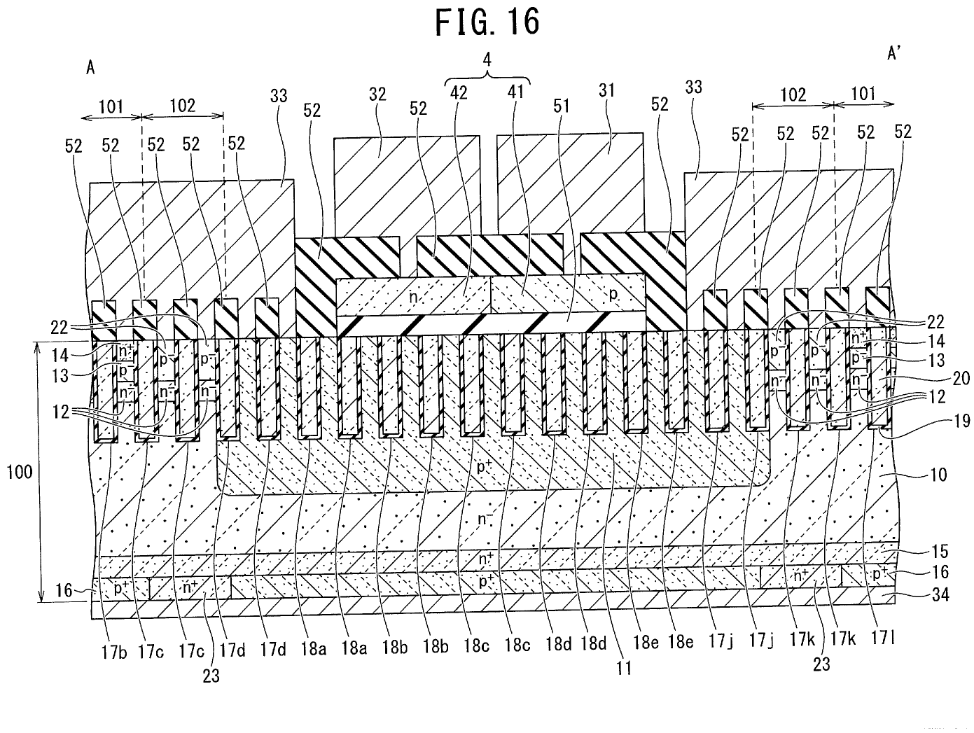

FIG. 16 is a cross-sectional view taken along line A-A′ in FIG. 15. As illustrated in FIG. 16, the n⁻-type accumulation layer 12 is provided on the top surface side of the n⁻-type drift layer 10 in the transistor part 101. The p⁻-type base region 13 is provided on the top surface side of the accumulation layer 12. The n⁺-type emitter region 14 and the p⁺-type contact region are provided on the top surface side of the base region 13. The accumulation layer 12, the base region 13, and the emitter region 14 in the transistor part 101 are in contact with the respective side surfaces of the trenches 17b, 17c, 17k, and 17l.

The n⁺-type buffer layer 15 is deposited on the bottom surface side of the drift layer 10 in the transistor part 101. The p⁺-type collector region 16 is further arranged on the bottom surface side of the buffer layer 15.

The n⁻-type accumulation layer 12 is provided on the top surface side of the n⁻-type drift layer 10 in the diode part 102. An anode region 22 of p⁻-type is provided on the top surface side of the accumulation layer 12. The anode region 22 can be formed simultaneously with the base region 13 in the transistor part 101. The accumulation layer 12 and the anode region 22 in the diode part 102 are in contact with the respective side surfaces of the trenches 17c, 17d, 17j, and 17k.

The n⁺-type buffer layer 15 is provided on the bottom surface side of the drift layer 10 in the diode part 102. A cathode region 23 of n⁺-type is provided on the bottom surface side of the buffer layer 15. The cathode region 23 is arranged in contact with the collector region 16 in the transistor part 101. The other configurations of the semiconductor device according to the second embodiment are substantially the same as those of the semiconductor device according to the first embodiment, and overlapping explanations are not repeated below.

The semiconductor device according to the second embodiment has the configuration in which, when the active region 1 is implemented by the RC-IGBT, the trenches 18a to 18e are provided inside the well region 11 located under the temperature detector 4. This configuration can prevent a stress concentration on the well region 11, so as to avoid a cause of slip around the temperature detector 4 during the heat treatment.

### Third Embodiment

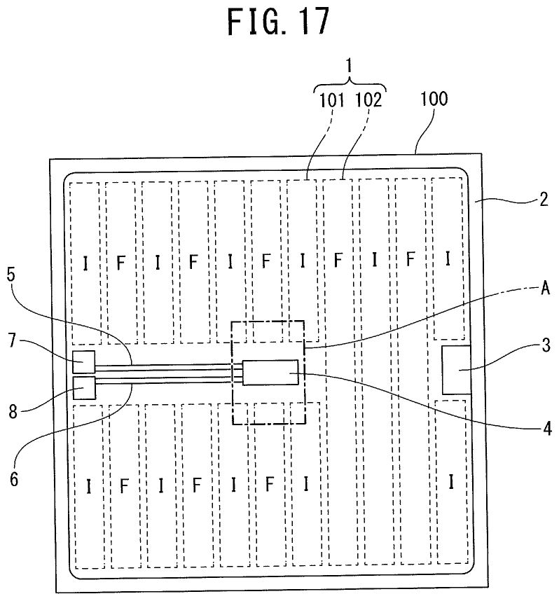

A semiconductor device according to a third embodiment differs from the semiconductor device according to the first embodiment in the arranged positions of the gate pad 3, the anode pad 7, and the cathode pad 8, as illustrated in FIG. 17. The semiconductor device according to the third embodiment further differs from the semiconductor device according to the first embodiment in that the active region 1 is implemented by a RC-IGBT.

The active region 1 includes the plural transistor parts 101 and the plural diode parts 102. FIG. 17 indicates the respective transistor parts 101 by sign “I” and the respective diode parts 102 by sign “F”. The respective transistor parts 101 and the respective diode parts 102 have a substantially rectangular planar pattern, and extend in the first direction (the upper-lower direction in FIG. 17). The respective transistor parts 101 and the respective diode parts 102 are alternately and periodically arranged in the second direction (the right-left direction in FIG. 17) perpendicular to the first direction.

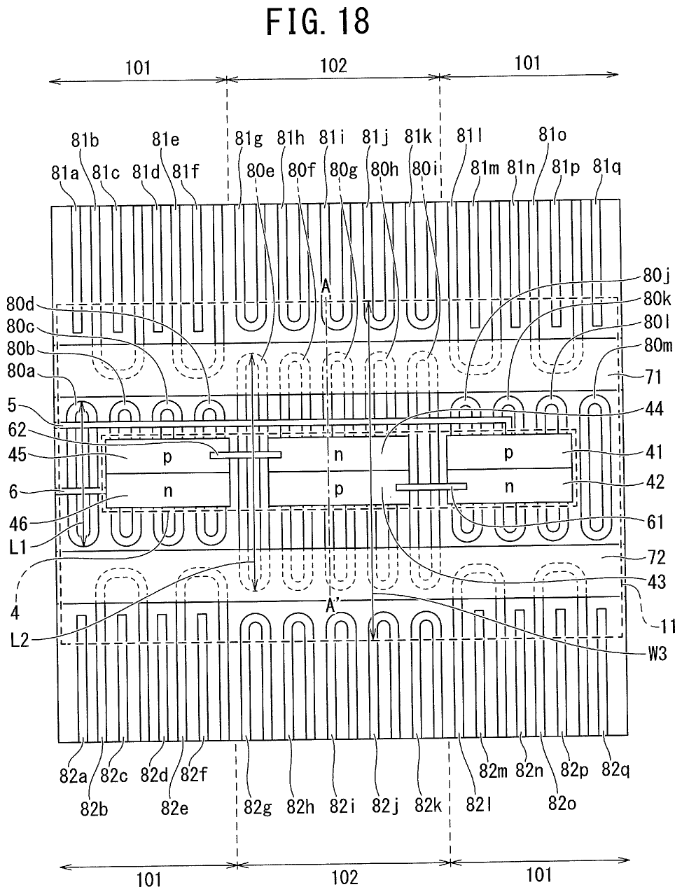

FIG. 18 is a schematic enlarged plan view of region A in FIG. 17. FIG. 18 schematically indicates the well region 11 by the broken line. As illustrated in FIG. 18, the temperature detector 4 is located inside the well region 11 to overlap with the well region 11 in the planar view. The first direction (the upper-lower direction in FIG. 18) corresponds to the short-side direction of the temperature detector 4 and the well region 11, and the second direction (the right-left direction in FIG. 18) corresponds to the longitudinal direction of the temperature detector 4 and the well region 11. The width W3 of the well region 11 in the first direction (the upper-lower direction in FIG. 18) is set in a range of about 100 micrometers or greater and 500 micrometers or smaller, and may be in a range of about 200 micrometers or greater and 300 micrometers or smaller, for example.

The temperature detector 4 includes a pair of the anode region 41 and the cathode region 42 in contact with each other in the first direction (the upper-lower direction in FIG. 18), a pair of an anode region 43 and a cathode region 44 in contact with each other in the first direction (the upper-lower direction in FIG. 18), and a pair of an anode region 45 and a cathode region 46 in contact with each other in the first direction (the upper-lower direction in FIG. 18). The respective pairs of the anode region 41 and the cathode region 42, the anode region 43 and the cathode region 44, and the anode region 45 and the cathode region 46 are aligned in the second direction (the right-left direction in FIG. 18) so as to be connected in series.

The anode region 41 is electrically connected to the anode pad 7 via the wire 5. The cathode region 42 implementing a p-n junction together with the anode region 41 is electrically connected to the anode region 43 via a wire 61. The cathode region 44 implementing a p-n junction together with the anode region 43 is electrically connected to the anode region 45 via a wire 62. The cathode region 46 implementing a p-n junction together with the anode region 45 is electrically connected to the cathode pad 8 via the wire 6.

Gate runners 71 and 72 are provided to interpose the temperature detector 4 in the first direction (the upper-lower direction in FIG. 18). The gate runners 71 and 72 are electrically connected to the gate pad 3 illustrated in FIG. 17.

The transistor part 101 includes trenches 81a to 81f and 81l to 81q located on one side of the temperature detector 4 in the first direction (the upper-lower direction in FIG. 18). The trenches 81a, 81c, 81d, 81f, 81m, 81n, 81p, and 81q each have an I-shaped planar pattern. The respective ends of the trenches 81a, 81c, 81d, 81f, 81m, 81n, 81p, and 81q are located at the positions overlapping with the well region 11 but not overlapping with the gate runner 71. The trenches 81a, 81c, 81d, and 81f are each a dummy trench not serving as an IGBT.

The trenches 81b, 81e, 81l, and 81o each have an O-shaped planar pattern. The respective ends of the trenches 81b, 81e, 81l, and 81o are located at the positions overlapping with the well region 11 and further overlapping with the gate runner 71. The trench 81b surrounds the circumference of the trench 81c. The trench 81e surrounds the circumference of the trench 81f. The trench 81l surrounds the circumference of the trench 81m. The trench 81o surrounds the circumference of the trench 81p. The trenches 81b, 81e, 81l, and 81o are each a gate trench serving as an IGBT.

The diode part 102 includes trenches 81g to 81k located on one side of the temperature detector 4 in the first direction (the upper-lower direction in FIG. 18) so as to be interposed between the trenches 81e and 81l in the transistor part 101. The trenches 81g to 81k each have an O-shaped planar pattern. The respective ends of the trenches 81g to 81k are located at the positions overlapping with the well region 11 but not overlapping with the gate runner 71.

The transistor part 101 includes trenches 82a to 82f and 82l to 82q located on the other side of the temperature detector 4 in the first direction (the upper-lower direction in FIG. 18). The trenches 82a, 82c, 82d, 82f, 82m, 82n, 82p, and 82q each have an I-shaped planar pattern. The respective ends of the trenches 82a, 82c, 82d, 82f, 82m, 82n, 82p, and 82q are located at the positions not overlapping with the gate runner 72. The trenches 82a, 82c, 82d, and 82f are each a dummy trench not serving as an IGBT.

The trenches 82b, 82e, 82l, and 82o each have an O-shaped planar pattern. The respective ends of the trenches 82b, 82e, 82l, and 82o are located at the positions overlapping with the gate runner 72. The trench 82b surrounds the circumference of the trench 82c. The trench 82e surrounds the circumference of the trench 82f. The trench 82l surrounds the circumference of the trench 82m. The trench 82o surrounds the circumference of the trench 82p. The trenches 82b, 82e, 82l, and 82o are each a gate trench serving as an IGBT.

The diode part 102 includes trenches 82g to 82k located on the other side of the temperature detector 4 in the first direction (the upper-lower direction in FIG. 18) so as to be interposed between the trenches 82e and 82l in the transistor part 101. The trenches 82g to 82k each have an O-shaped planar pattern. The respective ends of the trenches 82g to 82k are located at the positions not overlapping with the gate runner 72.

As illustrated in FIG. 18, trenches 80a to 80m are provided inside the well region 11 in the planar view. The trenches 80a to 80m each have an O-shaped planar pattern. The trenches 80a to 80m each include stripe parts extending in the first direction (the upper-lower direction in FIG. 18). A length L2 of the stripe parts of the respective trenches 80e to 80i is different from and longer than a length L1 of the stripe parts of the respective trenches 80a to 80d and 80j to 80m. The respective trenches 80a to 80m have substantially the same width as the respective trenches 81a to 81q. The respective trenches 80a to 80m in the second direction (the right-left direction in FIG. 18) perpendicular to the first direction have substantially the same pitch as the respective trenches 81a to 81q.

The respective one ends of the trenches 80a to 80d are located at the positions opposed to the respective ends of the trenches 81a to 81f, and are located at the positions not overlapping with the gate runner 71. The other ends of the trenches 80a to 80d are located to be opposed to the respective ends of the trenches 82a to 82f, and are located at the positions not overlapping with the gate runner 72. The respective trenches 80b to 80d are partly located immediately under the anode region 45 and the cathode region 46.

The respective one ends of the trenches 80e to 80i are located to be opposed to the respective ends of the trenches 81g to 81k, and are located at the positions overlapping with the gate runner 71. The other ends of the trenches 80e to 80i are located to be opposed to the respective ends of the trenches 82g to 82k, and are located at the positions overlapping with the gate runner 72. The respective trenches 80f to 80h are partly located immediately under the anode region 43 and the cathode region 44.

The respective one ends of the trenches 80j to 80m are located to be opposed to the respective ends of the trenches 81l to 81q, and are located at the positions not overlapping with the gate runner 71. The other ends of the trenches 80j to 80m are located to be opposed to the respective ends of the trenches 82l to 82q, and are located at the positions not overlapping with the gate runner 72. The respective trenches 80j to 80l are partly located immediately under the anode region 41 and the cathode region 42.

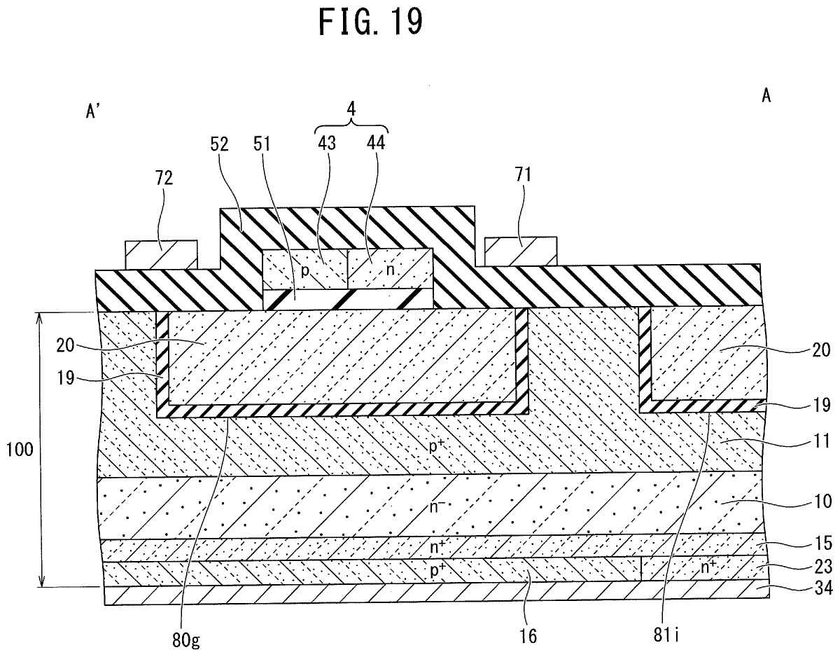

FIG. 19 is a cross-sectional view taken along line A-A′ passing across the temperature detector 4, the trench 81i, and the trench 80g in the first direction in FIG. 18 (the upper-lower direction in FIG. 18). As illustrated in FIG. 19, the p⁺-type well region 11 is provided on the top surface side of the n⁻-type drift layer 10. The trench 81i and 80g are located inside the well region 11. The end of the trench 81i is located to be opposed to the end of the trench 80g. The trench 80g is located immediately under the temperature detector 4. The other configurations of the semiconductor device according to the third embodiment are substantially the same as those of the semiconductor device according to the first embodiment, and overlapping explanations are not repeated below.

The semiconductor device according to the third embodiment has the configuration in which the trenches 80a to 80m are provided inside the well region 11 located under the temperature detector 4. This configuration can prevent a stress concentration on the well region 11, so as to avoid a cause of slip around the temperature detector 4 during the heat treatment.

### Fourth Embodiment

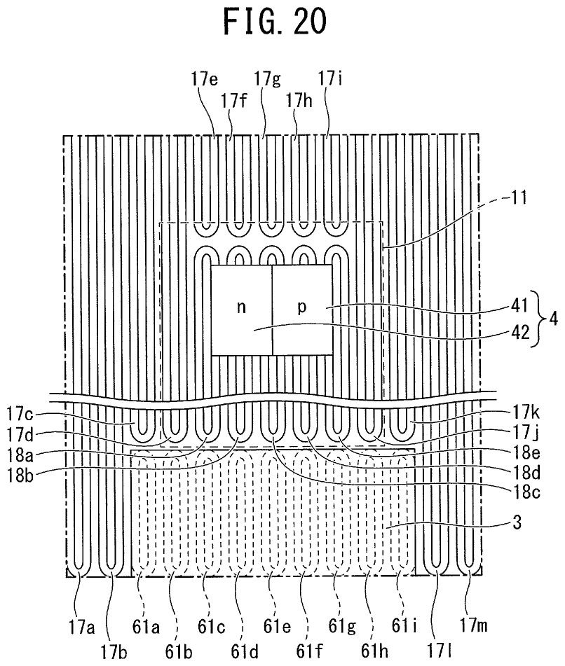

A semiconductor device according to a fourth embodiment differs from the semiconductor device according to the first embodiment in that trenches 61a to 61i are further provided on the lower side of the gate pad 3, as illustrated in FIG. 20. The trenches 61a to 61i each have an O-shaped planar pattern. The trenches 61a to 61i each include stripe parts extending in the first direction (the upper-lower direction in FIG. 20).

The respective ends of the trenches 61a, 61b, 61h, and 61i are located at the positions opposed to the respective ends of the trenches 17c, 17d, 17j, and 17k. The respective ends of the trenches 61c to 61g are located at the positions opposed to the respective ends of the trenches 18a to 18e. Additional trenches similar to the trenches 61a to 61i may further be provided on the lower side of the anode pad 7 and the cathode pad 8 illustrated in FIG. 1. The other configurations of the semiconductor device according to the fourth embodiment are substantially the same as those of the semiconductor device according to the first embodiment, and overlapping explanations are not repeated below.

The semiconductor device according to the fourth embodiment has the configuration in which the trenches 18a to 18e are provided inside the well region 11 located under the temperature detector 4. This configuration can avoid a cause of slip around the temperature detector 4 during the heat treatment. Further, the configuration including the trenches also on the lower side of the pads such as the gate pad 3, the anode pad 7, and the cathode pad 8 can avoid a cause of slip more reliably.

### Fifth Embodiment

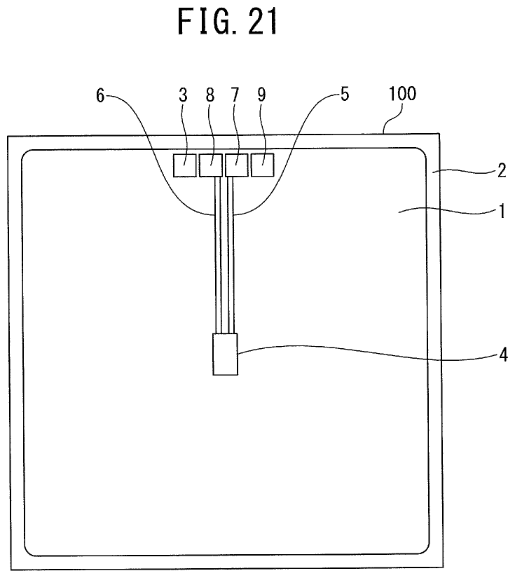

A semiconductor device according to a fifth embodiment differs from the semiconductor device according to the first embodiment in the positional relation between some elements including the gate pad 3, as illustrated in FIG. 21. The gate pad 3 is arranged next to the cathode pad 8. A sensing pad 9 is provided next to the anode pad 7 on the side opposite to the cathode pad 8. The sensing pad 9 is electrically connected to the emitter electrode of the IGBT in the active region 1. The other configurations of the semiconductor device according to the fifth embodiment are substantially the same as those of the semiconductor device according to the first embodiment, and overlapping explanations are not repeated below.

The semiconductor device according to the fifth embodiment has the configuration in which the trenches 18a to 18e are provided inside the well region 11 located under the temperature detector 4 as illustrated in FIG. 2 and FIG. 3, as in the case of the semiconductor device according to the first embodiment, while having the positional relation between the elements including the gate pad 3 different from that in the first embodiment. This configuration can prevent a stress concentration on the well region 11, so as to avoid a cause of slip around the temperature detector 4 during the heat treatment.

### Other Embodiments

As described above, the invention has been described according to the first to fifth embodiments, but it should not be understood that the description and drawings implementing a portion of this disclosure limit the invention. Various alternative embodiments of the present invention, examples, and operational techniques will be apparent to those skilled in the art from this disclosure.

For example, while the semiconductor device according to the first embodiment have been illustrated above with the case of using an IGBT having a trench gate structure as the active element in the active region 1, the present invention can also be applied to a MOSFET having a trench gate structure having a structure provided with an n⁺-type drain region instead of a p⁺-type collector region. The present invention can further be applied to a reverse-blocking insulated gate bipolar transistor (RB-IGBT).

In addition, the respective configurations disclosed in the first to fifth embodiments can be combined together as appropriate without contradiction with each other. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present specification.

What is claimed is:

1. A semiconductor device comprising:
a drift layer of a first conductivity-type;
a base region of a second conductivity-type provided on a top surface side of the drift layer;
a main region of the first conductivity-type provided on a top surface side of the base region;
a first gate electrode buried in a first trench in contact with the main region and the base region with a gate insulating film interposed;
a well region of the second conductivity-type provided on the top surface side of the drift layer;
a temperature detector provided on a top surface side of the well region with an insulating film interposed; and
a second gate electrode buried in a second trench provided in the well region and at least partly located immediately under the temperature detector with the gate insulating film interposed.

2. The semiconductor device of claim 1, wherein the first trench and the second trench each include a stripe part extending in a first direction in a planar view.

3. The semiconductor device of claim 2, wherein end parts of the first trench and the second trench are opposed to each other in the first direction.

4. The semiconductor device of claim 2, wherein:
the semiconductor device comprises a plurality of the first trenches and a plurality of the second trenches; and
the first trenches and the second trenches have a common pitch in a second direction perpendicular to the first direction.

5. The semiconductor device of claim 1, wherein the first trench and the second trench have a common width.

6. The semiconductor device of claim 2, wherein:
the semiconductor device comprises a plurality of the first trenches and a plurality of the second trenches; and
the second trenches are interposed between the first trenches in the first direction.

7. The semiconductor device of claim 2, wherein:
the semiconductor device comprises a plurality of the first trenches and a plurality of the second trenches; and
the second trenches are interposed between the first trenches in a second direction perpendicular to the first direction.

8. The semiconductor device of claim 1, wherein the second gate electrode has a floating potential.

9. The semiconductor device of claim 1, wherein the second gate electrode has a potential common to that of the main region.

10. The semiconductor device of claim 1, further comprising a gate pad electrically connected to the first gate electrode,
wherein a third trench is provided immediately under the gate pad.

11. The semiconductor device of claim 1, further comprising a pad electrically connected to the temperature detector,
wherein a third trench is provided immediately under the pad.

12. The semiconductor device of claim 1, wherein the temperature detector is implemented by a diode.

13. The semiconductor device of claim 2, wherein the semiconductor device comprises a plurality of the second trenches having different lengths in the first direction.

14. The semiconductor device of claim 2, wherein the well region has a rectangular planar pattern in which the first direction is a short-side direction.

15. The semiconductor device of claim 2, wherein the well region has a rectangular planar pattern in which a second direction perpendicular to the first direction is a short-side direction.

16. The semiconductor device of claim 14, wherein the well region has a width of 500 micrometers or smaller in the short-side direction of the planar pattern.
